(19) United States
(12) Patent Application Publication
(10) Pub. No.: US 2009/0314964 A1
(43) Pub. Date: Dec. 24, 2009

(54) ION-IMPLANTING APPARATUS

(75) Inventor: Yoshiro AOKI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/487,918

(22) Filed: Jun. 19, 2009

(30) Foreign Application Priority Data
Jun. 23, 2008 (JP) 2008-163655

(51) Int. Cl. H01L 21/265

(52) U.S. Cl. 250/492.21

(57) ABSTRACT

An ion-implanting apparatus comprising a holding unit that holds at least a semiconductor wafer and swings the wafer along a circular orbit, wherein an ion-beam is irradiated to a region that overlaps a part of the circular orbit; the holding unit comprises three or more holding pins that hold the wafer; the holding pins include a first type holding pin at least a portion of which being in contact with an edge of the wafer is made of a material selected from a thermo-setting resin and a photo-setting resin, and a second type holding pin at least a portion of which being in contact with the wafer is made of a material that contains graphite; and the first type holding pin of the plurality of holding pins is placed at a tail end position with respect to a direction of swinging the wafer.

### BACKGROUND ART

1. Field of the invention

The present invention relates to an ion-implanting apparatus that is used in implanting ions in substrates such as silicon wafers. Specifically, the present invention is related to an ion-implanting apparatus in which spinning of a wafer is inhibited and homogeneous thermal distribution in the wafer is realized.

Priority is claimed on Japanese Patent Application, No. 2008-163655, filed on Jun. 23, 2008, the content of which is incorporated herein by reference.

2. Background of the Invention

Conventionally, SOI (Silicon On Insulator) substrates have been paid attention to so as to realize semiconductor devices of high-speed performance and low electric power consumption. An SOI substrate has a buried oxide film of high insulation and a thin silicon layer (SOI layer) that covers the buried oxide film. By using this silicon layer as an active layer, it is possible to realize high-integrity, low electric power consumption, high-speed performance, and high-reliability of a semiconductor device.

The SOI substrates have been produced by a bonding method, a SIMOX (Separation by Implanted Oxygen) method, or the like (e.g., Patent Reference 1: U.S. Pat. No. 5,930,643). In the bonding method, an SOI substrate is formed by bonding two semiconductor wafers interposing an insulation film therebetween. In the SIMOX method, a SIMOX wafer (SOI substrate) is formed by implanting oxygen ions in a silicon wafer under heating conditions at a temperature of about 400 to 600° C. using an ion-implanting apparatus, and subsequently heating (annealing) the wafer at a higher temperature so as to form an oxide film in an interior of the silicon wafer. For example, Patent Reference 2 (Japanese Unexamined Patent Application, First Publication, No. 2003-45371) discloses an ion-implanting apparatus which can be used in the SIMOX method.

The ion-implanting apparatus described in Patent Reference 2 comprises a wheel-shaped substrate-support member, substrate-holding member that are joined to a hub of the support member via arms of the support member and holds the substrates, and a beam-line unit in which an ion beam is generated. A wafer loader unit is disposed to the ion-implanting apparatus so as to place each wafer on the substrate-holding member. The wafer is scanned by an ion-beam through rotation of the support member and/or vibration of the hub. By the irradiation of the ion-beam on a working surface of the wafer, the wafers are implanted with the ions. After that, each wafer is moved to the wafer-loader unit by rotation of the support member, and is carried out from the apparatus.

Patent Reference 3 (U.S. Pat. No. 6,794,662) proposes a constitution of an ion-implanting apparatus in which a wafer is held by a substrate-holder using a plurality of holding pins that are made to contact a circumferential edge of a wafer to hold the wafer. In the ion-implanting apparatus of such a structure, it is possible to simplify a mechanism of holding the wafer in the substrate-holder, reduce a contact area between the wafer and the substrate-holder, and suppress fracture of the wafer caused by rubbing of the wafer by the holding unit. In the apparatus of Patent Reference 3, the substrate holding pins are formed of thermosetting resins. If the holding pins are made of metallic materials, there is a possibility of contamination of the wafer by sputtering of the metal by the ion beam irradiated to the holding pins. Such a contamination can be avoided by forming the substrate holding pins of resin, and satisfactory ion implantation is enabled.

The SOI layer is separated from the bulk silicon wafer by the oxide film. The layer thickness of the SOI layer is an important dimension of the SOI substrate. The thickness of the SOI layer has a large influence on conditions in device production processes using the SOI substrate and on properties of the device. Therefore, there are demands for an SOI substrate not only having an SOI layer of a designated (target) thickness but also having the SOI layer of homogeneous thickness showing minimum fluctuation in layer thickness in the wafer.

For example, heterogeneity in the layer thickness of the SOI layer may be caused by thermal fluctuation in wafer plane during implanting ions into the wafer. Recently, it has been made clear that homogeneity of an SOI layer of an SOI substrate formed by the SIMOX method is largely influenced by temperature of the wafer during the time from the beginning of oxygen ion implantation to the completion of an SOI layer formation as well as by the amount of implanted oxygen ions (for example, O₂⁺) originating from the oxygen plasma and the energy of the implantation.

If the temperature of the wafer is not distributed homogeneously in the wafer plane after the oxygen ion implantation, diffusion of oxygen ions and reaction between the oxygen ions and the silicon layer may occur heterogeneously. As a result, inhomogeneous distribution of the layer thickness of the SOI layer in the wafer plane is expected.

When the ion implantation is performed, the wafer is heated by the energy of ion collision to the wafer, and is given a temperature higher than the processing conditions (working environments). If the wafer is held by pins as described in the above-described Patent Reference 3, the heat accumulated in the wafer is released through the substrate holding pins being in contact with the wafer. Therefore, the temperature of the wafer decreases in the vicinities of the holding pins compared to the other portions in the wafer, causing heterogeneous thermal distribution in the wafer. Such a thermal variation in the wafer plane may result in an inhomogeneous layer thickness of the SOI layer.

Ion implantation is performed under heating conditions. The ambient temperature at this time is similar to or higher than a glass transition temperature of a normal thermosetting resin. Therefore, the substrate holding pins made of resin are softened, and the wafer tends to be released from the held state. Therefore, during the ion implantation using an apparatus of a constitution described in Patent Reference 3, the wafer tends to spin (revolve) around an axis normal to the wafer plane while being in contact with the substrate holding pins. In general, a wafer is provided with a cut edge so called orientation flat or notch so as to control the orientation of the wafer in various processes. If the cut edge moves to the position of a substrate holding pin by the spinning of the wafer, there is a possibility that the wafer may fall due to loss of grip.

Based on the above-described circumstances, an object of the present invention is to provide an ion-implanting apparatus in which spinning of a wafer during ion implantation is suppressed and homogeneous thermal distribution in the wafer is realized consistently.

### SUMMARY OF THE INVENTION

As a result of extensive research to solve the above-described problem, the inventors found that wafer spinning during ion implantation can be suppressed and homogeneous thermal distribution can be realized consistently by selecting preferable materials to form substrate holding pins in accordance with arrangement positions where the pins hold the wafer.

An ion-implanting apparatus of the present invention comprises an holding unit (supporting unit) that holds (supports) at least a semiconductor wafer and swings the wafer along a circular orbit, wherein an ion-beam is irradiated to a region that overlaps a part of the circular orbit to implant ions in the wafer; the holding unit comprises three or more holding pins that hold the wafer by being in contact with a circumference edge of the wafer, the holding pins include a first type holding pin at least a portion of which being in contact with an edge of the wafer is made of a material selected from a thermo-setting resin and a photo-setting resin, and a second type holding pin at least a portion of which being in contact with the wafer is made of a material that contains graphite; and the first type holding pin of the plurality of holding pins is placed at a tail (back) end position with respect to the direction of swinging the wafer.

In the above-described ion-implanting device, the holding unit may comprises a plurality of wafer-holders, and holds a plurality of semiconductor wafers on the wafer-holders, wherein each of the wafers is held by the three or more of the holding pins on the wafer-holder, and the first type holding pin of the plurality of holding pins is placed at a tail (back) end position with respect to the direction of swinging the wafer.

In the above-described ion-implanting apparatus, the wafer-holding unit may swing the plurality of semiconductor wafers along the same circular orbit.

As a result of investigation by the inventors, it was discovered that thermal gradients (inclinations in thermal distribution ) tend to occur at a portion in the vicinity of holding pins positioned in the back side with respect to the circulation direction of the wafer in the wafer during the ion implantation. That is, heat of the substrate easily dissipates from the above-described portions. In the present invention, since the first pin placed in the above-described position is constituted of a material having a low heat conductivity selected from thermo-setting resin and photo-setting resin, it is possible to suppress the occurrence of inclined thermal distribution.

Further, since the second pin made of a material containing graphite satisfactorily holds the wafer, it is possible to prevent the wafer from spinning during the ion-implantation.

By the above-described constitution, it is possible to prevent the wafer from falling by preventing the wafer from spinning during the ion-implantation. Further, it is possible to suppress the occurrence of thermal inclination in the vicinity of the contact portions where the wafer is in contact with the holding pins. Therefore, satisfactory ion-implantation can be performed by the ion-implanting apparatus of the above-described constitution. In the above-described circumferential edge of a wafer denotes a peripheral plane extending in the thickness direction from the edge of a front surface of a wafer to an edge of a back surface of a wafer and a portion formed by beveling (grinding) the edges of the wafer surfaces.

In the present invention, a material that constitutes the first type holding pin is preferably a polyimide resin having resistivity of 0.1 Ω·cm or more and 100 Ω·cm or less.

Since the polyimide resin having the above-described low resistivity has high electro-conductivity, it is possible to release electric charge charged on the wafer by the ion-implantation. Therefore, in addition to the above-described advantage, it is possible to suppress the deformation of the wafer by the electric charging of the wafer.

According to the present invention, by constituting the pins that holds a wafer of different materials in accordance with the arrangement position of each of the pins, it is possible to provide an ion-implanting apparatus that ensures suppression of spinning of the wafer and homogeneous thermal distribution in the wafer consistently, thereby forming an SOI layer having a constant thickness.

### BRIEF EXPLANATION OF DRAWING

FIG. 1A is a schematic perspective diagram of an ion-implanting apparatus according to the present invention.

FIG. 1B is a schematic diagram (side view) showing an operation process of the ion-implanting apparatus.

FIG. 2 is a schematic perspective diagram of a holding unit of an ion-implanting apparatus according to the present invention.

FIG. 3 is a schematic diagram of a wafer-holder of the holding unit.

FIG. 3A is a schematic perspective view of a wafer holder.

FIG. 3B is a schematic front view of the wafer holder shown in FIG. 3A at a state holding a wafer.

FIG. 3C is a schematic side view of the wafer holder shown in FIG. 3B.

FIG. 4 is a schematic side view of a wafer-holding pin.

FIG. 5 is a schematic diagram showing a process of ion-implantation to a wafer held by holding pins.

FIG. 6A is a schematic diagram showing a transfer of heat accumulated in a wafer in the vicinity of a holding pin positioned in front side with respect to the swinging direction of the wafer.

FIG. 6B shows a schematic diagram showing a transfer of heat accumulated in a wafer in the vicinity of a holding pin positioned in tail side with respect to the swinging direction of the wafer.

FIG. 7A is a schematic side view of an alternative embodiment (modified form) of a second type holding pin.

FIG. 7B is a schematic side view of another alternative embodiment of a second type holding pin.

FIG. 8 is a graph showing an arrangement of three holding pins in Example.

### DETAILED DESCRIPTION OF THE INVENTION

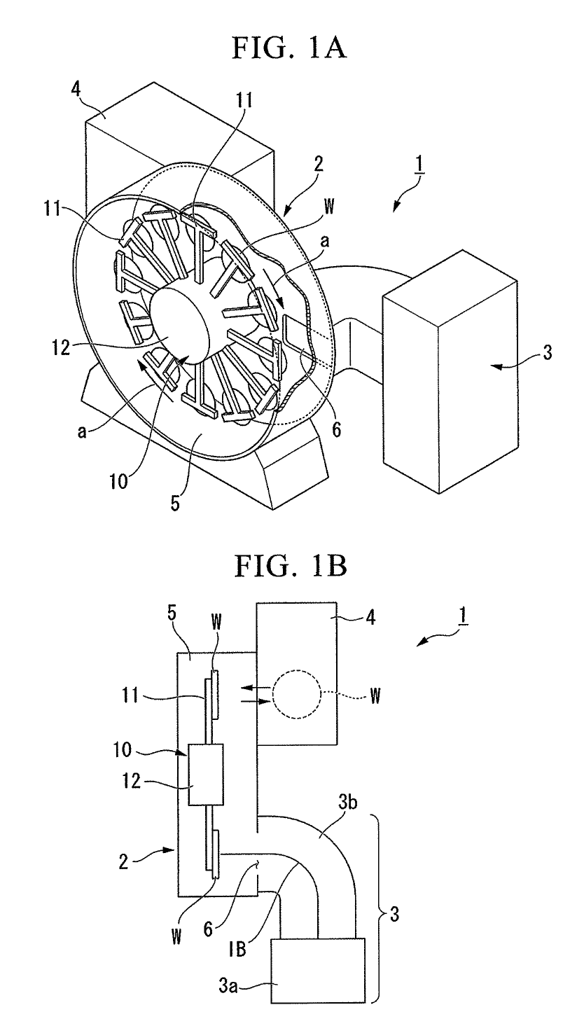

In the following, an ion-implanting apparatus according an embodiment of the present invention is explained with reference to FIGS. 1 to 7. In the following explanation, the ion-implanting apparatus of the present embodiment is applied to the fabrication of an SOI substrate by implanting oxygen ions in a silicon wafer in accordance with the SIMOX method. It should be noted that all of the drawings are schematic diagrams where thickness and dimension of each constituents are, where necessary, modified from practical values so as to visualize the constituents conveniently.

FIGS. 1A and 1B are schematic diagrams showing an ion-implanting apparatus 1 of the present embodiment. FIG. 1A is a perspective view of the apparatus 1. FIG. 1B is a schematic diagram showing an operation process of the ion-implanting apparatus 1.

As shown in FIG. 1A, the ion-implanting apparatus 1 comprises an ion-implanting unit 2 where at least a semiconductor wafer (for example, silicon wafer) W is implanted with ions, ion-beam generating unit 3 to generate the ion beam to be radiated on the wafer W, wafer-carrier unit (wafer-loader unit) 4 that is used in carrying in the wafer W in a chamber 5 of the ion-implanting unit 2 and carrying out the wafer W from the chamber 5. A holding unit (holding device) 10 is disposed in the chamber 5. The holding unit 10 holds a plurality of wafers W. An injection port 6 is formed in a wall 5 of the chamber 5. The ion-beam generated in the ion-beam generating unit 3 is introduced in the chamber 5 through the injection port 6. During the ion-implantation process, the interior of the chamber is evacuated to a predetermined vacuum level by a vacuum pump (not shown), and is heated to a temperature appropriate for ion-implantation.

Holding unit 10 comprises a plurality of wafer-holders 11 and a hub 12. Each wafer-holder 11 has two ends. The wafer-holder 11 holds a wafer W on one end (end portion), and is connected to the hub 12 at another end. Thus, the plurality of wafer-holders 11 are connected to the hub 12. The plurality of wafer-holders are disposed such that the wafer-holders 11 elongate in the radial direction from the hub 12. The holding unit 10 is constituted such that the plurality of wafer-holders 11 and the wafers W held on the wafer-holders are swung by rotation of the hub 12 in a direction shown by the arrow a. For example, the holding unit 10 is rotated at a rate of 70 rpm. By the rotation of the holding unit 10 (rotation of the hub 12), the wafers W held on the wafer-holders 11 are swung along a circular orbit about a rotation axis of the hub 12.

The circular orbit (locus) of swinging a wafer W and the injection port 6 are arranged on the same plane. Along with the swinging of the holding unit 10, ion-beam injected from the injection port 6 is irradiated to a plurality of wafers W. In the ion-implanting apparatus 1 of the present embodiment, oxygen ions originating from oxygen plasma are generated in the ion-beam generation unit 3 so as to implant oxygen ions in the wafer W. Although not shown in FIG. 1A, the ion-implanting apparatus includes additional devices such as a swinging mechanism of the holding unit 10 and a beam stopper disposed at a position opposing to the injection port.

As shown in FIG. 1B, the ion beam generation unit 3 includes an ion-generation device 3a and an mass spectroscopic device 3b. In the ion-generation device 3a, ions to be implanted are generated by electric discharge in a gas. In the mass spectroscopic device 3b, magnetic field is applied to the ions transmitting in the unit, thereby selectively extracting ions of desired (target) mass from the unit. The ions generated in the ion-generation device 3a are extracted by the electrodes (not shown), accelerated, and subsequently converted to ion beam IB only including the desired ion species by transmitting the mass spectroscopic device 3b. The ion beam IB is irradiated to a wafer W held by the wafer holder 11 at a position facing the injection port 6. Thus, the wafer W is implanted with ions.

After completion of the ion-implantation, the wafer W is moved by a motion of the holding unit to a carrying-out position, and is carried out from the chamber 5 by the wafer-carrier unit 4. After removal of the ion-implanted wafer W, a new wafer W is placed on the wafer holder by the wafer-carrier unit 4, and is subjected to ion-implantation in a similar manner.

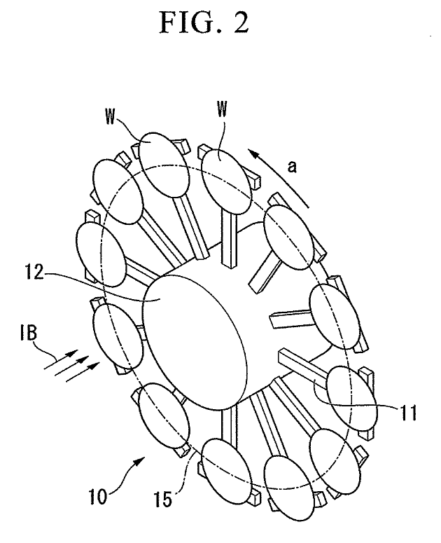

FIG. 2 is a diagram showing a schematic perspective view of a holding unit 10 as a main constituent of the ion-implanting apparatus 1. Compared to FIG. 1, the opposite side of the holding unit 10 is shown in FIG. 2.

The holding unit 10 is constituted such that a plurality of wafers W are held along a circle (virtual circle) around a center at a rotation axis of the hub 12. Ion-beam IB injected from the injection port 6 is irradiated to a region overlapping a portion of the circle on which the wafers W are arranged. By swinging a plurality of wafers in the direction shown by the arrow a due to the rotation of the holding unit 10, the plurality of wafers W pass the region irradiated with the ion beam IB one by one. Thus, all of the wafers are implanted with ions.

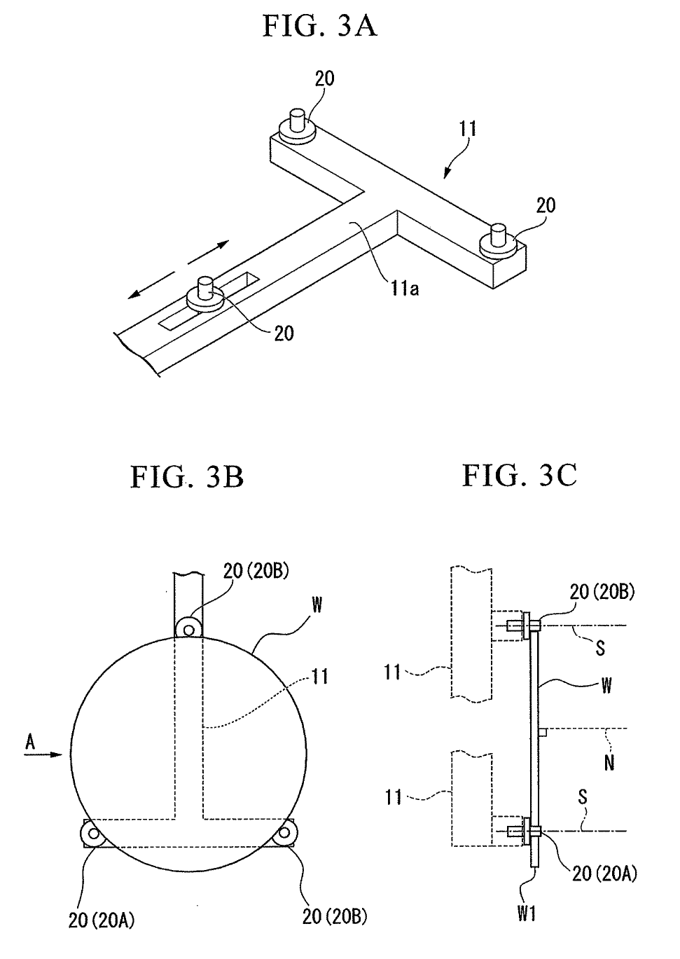

FIGS. 3A, 3B, and 3C are schematic diagrams showing a wafer holder 11 of the holding unit 10. FIG. 3A shows a schematic perspective view of the wafer holder 11. FIG. 3B is a front view of the wafer holder 11 in a state of holding a wafer, where the figure is viewed from above a working surface (surface to be treated) of the wafer. FIG. 3C is a side view viewed from the left side of the wafer holder 11 shown in FIG. 3B along the arrow A.

As shown in FIG. 3A, the wafer holder 11 has a support body 11a and holding pins 20 disposed at three positions of the support body 11a. The support body 11 shows a substantially T-shape form, where a bar (longitudinal bar) that constitute a vertical line of a T-shape is connected to a bar (transverse bar) that constitutes a transverse line of the T-shape. Two of the three holding pins 20 are fixed to tow ends of the transverse bar. One of the holding pins 20 is disposed to the longitudinal bar such that such that the pin is moveable along the vertical line of the T-shape.

Although FIG. 3A shows a constitution in that a transverse bar is integrated with a longitudinal bar that is connected to the mid-portion of the transverse bar, shape of the wafer-holder is not limited to the illustrated form. For example, the end portion of the longitudinal bar may be branched to form a substantially Y-shape, and is connected to two portions of the transverse bar.

As shown in FIG. 3B, when a wafer W is held in the wafer holder 11, the movable holding pin 20 is moved towards the fixed holding pins 20 (towards the transverse bar) so as to catch the wafer W by the fixed holding pins 20 and the movable holding pin 20, thereby supporting the wafer W at three points.

As shown in FIG. 3C, at a state holding the wafer W, the holding pins 20 are disposed such that axial lines S of the holding pins 20 are parallel to a normal line N to a surface plane of the wafer W.

In the present invention, as explained in the following, the holding pins 20 are constituted of different materials in accordance with the arranged positions on the wafer holder 11.

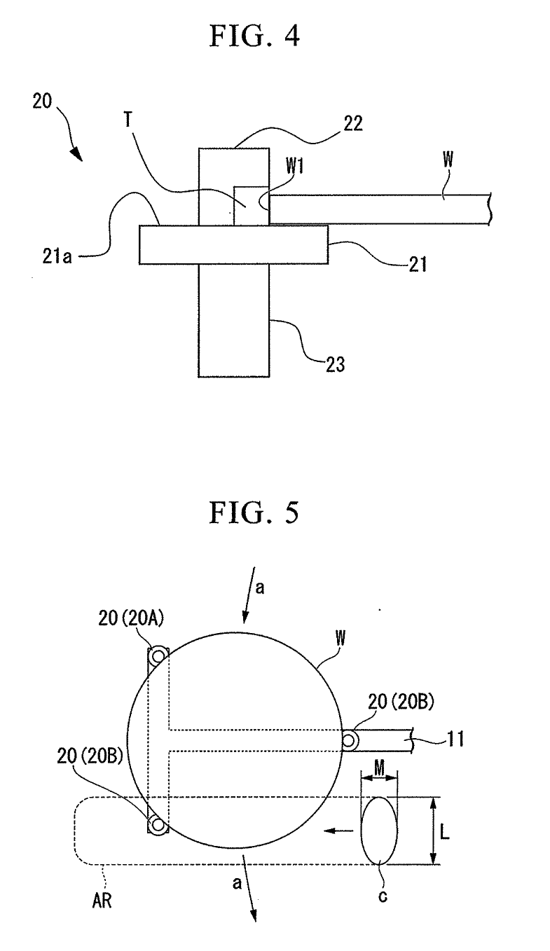

FIG. 4 is a schematic side view of a holding pin 20. As shown in FIG. 4, the holding pin 20 has a flange portion 21, a support portion 22, and a fixing portion 23. The flange portion 21 has a surface 21a that is made to contact a back surface (a surface on the reverse side of the working surface) of the wafer W. The support portion 22 protrudes from the surface 21a of the flange potion 21 and is made to contact the circumferential edge W1 of the wafer W. The fixing portion 23 is connected to the flange portion 21 at one end, and is connected (fit) to a wafer holder 11 (not shown in FIG. 4) at another end. A basal portion (a vicinity to the flange portion 21) of the support portion 22 has a contact portion T that is made to contact the circumferential edge W1 of the wafer W. Radial sections of the support portion and the contact portion T have substantially circular shapes.

For example, in order to hold a wafer of 300 mm in diameter, holding pins 20 may have the following dimensions. Dimensions of a flange portion 21 may be controlled as follows. The diameter of the flange portion may be 1 to 3 cm. The thickness of the flange portion 21 may be 3 to 5 mm. The diameter of the support portion 22 may be 5 to 10 mm. The vertical dimension (length) of the support portion 22 may be 5 to 15 mm. The fixing portion 23 may have the same diameter as the support portion 22 and have a vertical dimension (length) of 10 to 30 mm.

Conventionally, thermosetting resin, graphite, and composite material composed of thermosetting resin and graphite have been known as materials for holding pins. However, combined use of holding pins made of different materials were not attempted.

Since a thermosetting resin has low heat conductivity, it may contribute to maintaining homogeneous thermal distribution in the wafer. However, bending strength of the thermosetting resin deteriorates by softening under a high temperature condition, making it difficult to support a wafer W under an influence of centrifugal force caused by the circulation of the holding unit 10. As a result, the wafer W tends to spin during the ion-implantation, and easily falls down during the ion-implantation process. A material that contains graphite may escape from softening under a high temperature condition and maintain bending strength. However, because of the high heat conductivity, heat dissipates through the contact portion between the holding pins and the wafer W, causing it difficult to maintain thermal homogeneity in the wafer W during the ion-implantation.

Therefore, in the holding pins 20 according to the present invention, a first type holding pin 20A made of thermosetting resin, and second type holding pins 20B made of graphite-containing material are used in combination. In the present embodiment, the second type holding pins 20B are made of a composite material that contains a constituent material of the first type holding pin 20A and graphite.

Super engineering plastic resin being stable for a long time under high temperature environment may be satisfactorily applied as the thermosetting resin as a constituent material of the first type holding pin 20A. For example, polyimide resin, polyamide-imide resin, polyetheretherketone (PEEK), or the like may be used.

Preferably, polyimide resin having an electric conductivity may be used. By the use of such a polyimide resin, it is possible to remove electrons charged in the wafer by the ion-implantation. Therefore, it is possible to prevent disadvantageous phenomena such as deformation of an oxide film by the electrons charged in the wafer, and electric discharge between the wafer and surrounding members. Where defined by a reciprocal (inverse number) of the electric conductivity, the polyimide resin may have a resistivity of 0.1 Ω·cm or more and 100 Ω·cm or less. For example, the resistivity may be measured in accordance with the “method of testing resistivity of an electric-conductive plastic resin by 4 probe method” regulated by JIS K7194. It is allowable to mix additive agent to the resin to provide electric conductivity, thereby forming the holding pin 20A.

Each of the second type holding pins 20B may be constituted of a composite material consisting of thermosetting resin as a constituent material of the first type holding pin 20A and graphite. In the present embodiment, a preform having a shape of the second type holding pin 20B is formed of polyimide resin. After that, the preform is heated at a temperature of about 200 to 300° C. for 20 to 30 minutes in a reducing atmosphere so as to carbonize the surface portion. Thus a second type holding pin 20B having a graphite layer of 0.1 to 500 μm uniformly formed in the surface portion and interior portion made of polyimide resin is formed.

In the ion-implanting apparatus of the present embodiment, one pin has the constitution of the first type holding pin 20A and two pins have a constitution of the second type holding pin 20B. Therefore, low heat conductivity of the thermosetting resin, and rigidity of graphite containing material are both provided in this embodiment.

Next, arrangement of the first type holding pin 20A and the second type holding pins 20B is explained with reference to FIG. 5. FIG. 5 is a schematic drawing exemplifying a process of ion beam irradiation to a wafer W held by the holding pins 20 on the wafer holder 11.

For example, the ion beam IB may be irradiated to an area of elliptic shape having a major axis L and minor axis M. Such an ion beam is scanned along a direction crossing the direction of an arrow a such that the ion beam IB is irradiated to the region IB. For example, scanning of the ion beam IB may be performed by applying an electric field or a magnetic field to the ion beam IB where the ion beam IB is injected from the ion beam generation unit shown in FIG. 1, thereby bending the ion beam to the scanning direction. On the other hand, the wafer held by the holding pins 20 is moved in the direction shown by the arrow along with the circulation of the holding unit 10. Then the band-shaped region AR (ion-beam irradiated region) to which the ion-beam is irradiated passes across the wafer W (In other words, the wafer W passes across the region AR).

Where the ion-beam irradiation is performed in such a manner, the following temperature change is expected in the vicinity of the portion being in contact with the holding pins 20.

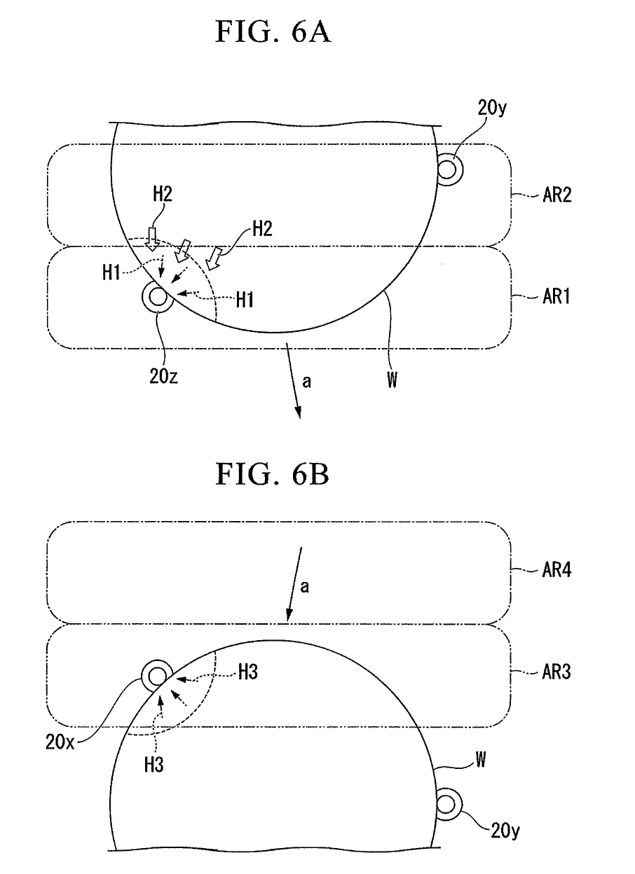

FIGS. 6A and 6B are schematic drawings that show a behavior of transfer of heat accumulated in the wafer W. FIG. 6A shows a temperature change in the vicinity of holding pin 20z positioned at the front side with respect to the swinging direction shown by the arrow a, and FIG. 6B shows a temperature change in the vicinity of holding pin 20x positioned at the tail side with respect to the swinging direction shown by the arrow a.

As shown in FIG. 6A, oxygen ions are implanted to the wafer W in a portion overlapping (facing) the region AR1. At the same time, the portion of the wafer overlapping the region AR is heated by the energy given by the ion-implantation.

In accordance with the movement of the wafer W in the swinging direction shown by the arrow a, ion-beam irradiation region moves on the wafer. After the ion-beam irradiation to the region AR1, for example, by one back-and-forth scanning, thereby irradiating the ions to the portion overlapping the region AR1 (heating the portion overlapping the region AR1), next scanning irradiates the ion-beam to a different portion overlapping the region AR2. Viewed from the wafer, the region AR2 is different from the region AR1.

During the ion-beam irradiation to the portion overlapping the region AR2, heat (calorie) H1 accumulated in the portion overlapping the region AR1 dissipates through the holding pin 20z being in contact with the wafer W.

At the same time, heat H2 is supplied to the vicinity of the holding pin 20z by heat conduction in the wafer W from the heated portion overlapping the region AR2. Therefore, an abrupt decrease of temperature does not occur after the ion implantation in the vicinity of the holding pin 20z, where inclined thermal distribution does not tend to occur in the wafer. The above-explained redistribution of heat also occurs in the portion (portion of the waver W) in the vicinity of holding pin 20y.

As shown in FIG. 6B, in the vicinity of the holding pin 20w, the portion of the wafer W overlapping the region AR3 is heated by the ion-beam irradiated to the region AR3. The accumulated heat H3 dissipates through the holding pin 20z. On the other hand, since the region AR4 to which the ion-beam is irradiated by the next scanning does not face the wafer W (or faces the adjacent wafer W), no heat is supplied to the vicinity of the holding pin 20x from the tail side with respect to the direction shown by arrow a. Therefore, in the vicinity of the holding pin 20x, temperature of the wafer W decrease abruptly after the ion-implantation, and the wafer tends to occur inclined thermal distribution.

Therefore, in the ion-implanting apparatus 1 of the present embodiment, the first type holding pin 20A made of thermosetting resin having low heat conductivity is applied to the holding pin 20z tending to cause cooling of its vicinity so as to suppress the heat dissipation to a small value. As the another holding pins 20y and 20z that are not ready to cause abrupt cooling of the wafer, second type holding pins 20B are applied so as to prevent spinning of the wafer W. Compared to the first type holding pin 20A, the second type holding pin 20B tends to dissipate heat, but securely holds the wafer because of its resistance to heat softening.

By the thus selecting preferable materials for holding pins 20 in accordance with their arrangements, it is possible to prevent spinning of the wafer and inhibit the occurrence of inclined thermal distribution consistently.

By using the ion-implanting apparatus 1 of the above-described constitution, it is possible to prevent spinning of the wafer W during the ion-implantation, thereby preventing falling of the wafer. At the same time, occurrence of thermal inclination in the wafer in the vicinity of the portion being in contact with the holding pins is inhibited. Therefore, it is possible to produce high-quality SOI substrates by satisfactory ion-implantation.

According to the present embodiment, constituent material of the first type holding pin is a polyimide resin having a resistivity of about 0.1 Ω·cm or more and 100 Ω·cm or less. Therefore, it is possible to perform satisfactory ion-implantation while suppressing charging of the wafer W by the ion-implantation, thereby forming an SOI substrate of high-quality.

In the above-described explanation of the present embodiment, ion-implanting apparatus 1 was applied to a SIMOX method to form an SOI substrate by implanting oxygen ions to a silicon wafer. SIMOX method includes several procedures such as the High Dose SIMOX method, the Low Dose SIMOX method, and the MLD (Modified Low Dose) method. The ion-implanting apparatus of the present embodiment may be applied to any of the generally known specific SIMOX methods.

While the implanted ions are described as oxygen ions in the above-explained embodiment to produce an SOI substrate, it is possible to implant different species of ions in accordance with specific purposes.

While the first type holding pin in the present embodiment was explained to be constituted of a thermosetting resin, it is possible to use photo-setting resin provided that the photo setting resin has heat resistance sufficient to be used under a high temperature environment at the time of ion-implantation.

In the above-described explanation of the present embodiment, the second type holding pin was constituted of polyimide resin having a surface coated with graphite. Alternatively, the second type holding pin may be constituted of a material of a different structure. For example, the second type holding pins may be constituted of composite material comprising a polyimide resin and graphite grains of about 10 to 100 μm in grain size uniformly dispersed in the polyimide resin.

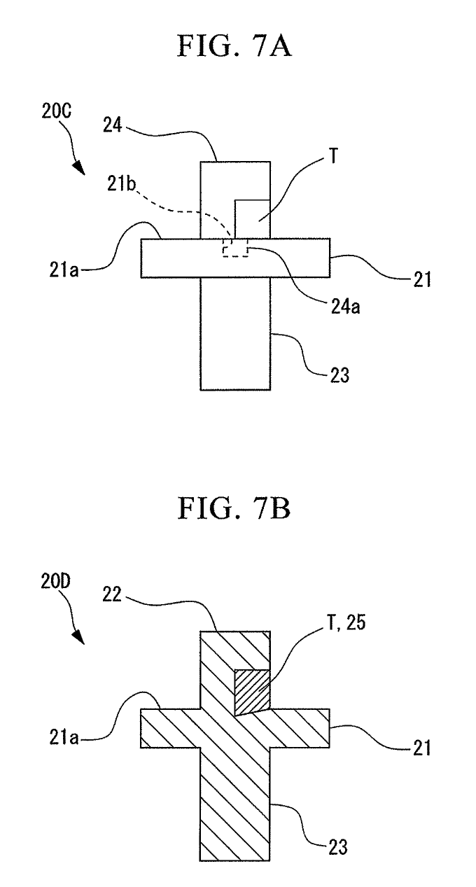

In the present invention, constituent material of the second type holding pin is selected from materials containing graphite that escapes from softening under high temperature environment so as to ensure secure holding while preventing high temperature softening of the holding pins. Where this scope is satisfied, the above-described form (shape) of the holding pin may be modified to alternative forms. Several alternative embodiments (modified forms) of the second type holding pins are explained in the following. FIGS. 7A and 7B show schematic diagrams of the alternative embodiments.

FIG. 7A is a side view showing a first alternative embodiment in comparison to FIG. 4. As shown in the figure, the flange portion 21 and the fixing portion 23 of the second type holding pin 20C are made of thermosetting resin like the first type holding pin. Only the holding portion 24 is made of material containing graphite. The holding portion 24 has a protruding portion 24a in the end portion facing the flange 21 portion. The protruding portion is fit in the fixing hole 21b formed in the flange portion 21 so as to be fixed to the flange portion 21. Alternatively, it is allowable to form a fixing hole in the holding portion 24 and to form a protruding portion in the flange portion 21. Further, it is possible to provide internal thread to the fixing hole and external thread to the protruding portion so as to ensure tight fixture by screwing.

In the second type holding pin 20C of such a constitution, it is possible to prevent spinning of the wafer W by holding the wafer by the holding portion 24. In addition, since the flange portion 21 and the fixing portion 23 are made of thermosetting resin having low heat conductivity, it is possible to reduce the heat dissipation from the wafer W. Therefore, it is possible to prevent formation of an SOI layer having inhomogeneous thickness in the vicinities of the portions being in contact with the second type holding pins 21C.

FIG. 7B shows a schematic cross section of a second alternative embodiment. The flange portion 21, fixing portion 23, and holding portion 22 are mostly composed of thermosetting resin and are integrated with each other. Only the contact portion T is constituted of contact member 25 made of a material containing graphite. A fixing hole is formed in the holding member 22 to accept the contact portion T. The contact member 25 constituting the contact portion T is fit in the hole so as to be fixed to the holding portion 22.

Along the radial direction from the axis of the holding portion 22 to the contact face (along the direction in parallel to the plane of the wafer being contact with the contact member), the contact member 25 may have a dimension (depth) within a range of 0.5 mm to 1 cm. The contact member may have a vertical dimension (height) (dimension along the thickness of the wafer) in the range of about 1.5 mm to 5 mm, and a width (dimension along the direction vertical to the depth) (dimension in parallel to the tangent line of the wafer edge) in the range of about 1.5 mm to 5 mm.

In the second type holding pin 20D of such a constitution, since the contact member 25 disposed in the contact portion T is made of material containing graphite, it is possible to prevent spinning of the wafer. In addition, since the flange portion 21 and the fixing portion 23 are made of thermosetting resins having low heat conductivity, it is possible to reduce the heat dissipation from the wafer W, thereby further homogenizing the thickness of the SOI layer.

As examples of the other embodiments, it is allowable to constitute the contact member of cylindrical contact member fit around a holding member of smaller diameter, or to constitute the contact member of bar-shaped graphite fit in the fixing through-hole formed in the radial direction of the holding portion.

The ion-implanting apparatus having the second type holding pins of the above-described alternative constitution may also inhibit the spinning of wafer during the ion implantation.

### EXAMPLES

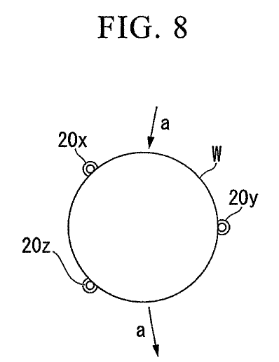

As an example of the present invention, ion-implantation of wafers was performed while varying the material of holding pins that hold the wafers. In the present example, evaluation was made based on the ion-implantation in accordance with MLD-SIMOX method to perform low-dose oxygen ion implantation in two times. FIG. 8 is an explanatory drawing that shows an arrangement of holding pins that holds an wafer. Conditions (arrangement of holding pins) and results of evaluation are shown in Tables 1 and 2.

In the present example, occurrence or absence of spinning of the wafer during the ion-implantation and film thickness (layer thickness) of the formed SOI layer were evaluated. In the present example, occurrence or absence of the wafer spinning was examined based on the change of position of the notch formed in the each wafer. In each wafer, the thickness of the formed SOI layer was measured in several positions, and the difference between the largest thickness and smallest thickness was denoted as the thickness range and was listed in Tables 1 and 2. A small thickness range shows a satisfactory state of the SOI substrate having a SOI layer of homogeneous thickness.

In the present example, as shown in FIG. 8, each wafer was held by three holding pins. Each of the three holding pins were named (symbolized) 20x, 20y, 20z in accordance with their arrangement from the tail side to the front side with respect to the swinging direction of the wafer shown by the arrows a. Under each of conditions of the following Experiment A or Experiment B, SOI substrates were produced in the same manner besides the difference in materials constituting the holding pins. Occurrence or absence of spinning of the wafer during the ion-implantation process, and thickness of the SOI layer was evaluated for each case.

### Experiment A

In Example 1, a holding pin 20x positioned at the tail end with respect to the swinging direction of the wafer W was constituted of the first type holding pin A made of a thermosetting resin, and the other holding pins 20y and 20z were constituted of the second type holding pins 20B each made of material containing graphite. In Example 2, holding pin 20y was constituted of the second type holding pin 20B, and holding pins 20x and 20z were constituted of the holding pins 20A. In Comparative Example 1, all of the three holding pins were made of resin having a constitution of holding pin 20A. In Comparative Example 2, all of the thee holding pins were made to have the constitution of holding pin 20B made of material containing graphite.

In each of Examples 1, 2, and Comparative Examples 1, 2, ion-implantation conditions were controlled such that implantation energy of 178 keV and implantation dose of 2.4×10¹⁷ atoms/cm² were applied for the first time oxygen ion implantation, and implantation energy of 164 keV and implantation dose of 6.0×10¹⁵ atoms/cm² were applied for the second time oxygen ion implantation. The results of evaluation were shown in Table 1.

TABLE 1

| | | | | | Thickness |
|---|---|---|---|---|---|
| | | | | | range of SOI |
| | | | | Spinning of | layer |
| | 20x | 20y | 20z | wafer | (Å) |
| Example 1 | 20A | 20B | 20B | absent | 19 |
| | (resin) | (graphite | | absent | 19 |
| | | containing | | absent | 18 |
| | | composite) | | absent | 20 |
| Example 2 | 20B | 20B | 20A | absent | 19 |
| | | | | absent | 19 |
| | | | | absent | 20 |
| | | | | absent | 19 |
| Comparative | 20A | 20A | 20A | occurred | 18 |
| Example 1 | | | | occurred | 15 |
| | | | | occurred | 18 |
| Comparative | 20B | 20B | 20B | absent | 30 |
| Example 2 | | | | | |

20A: holding pin made of thermosetting resin
20B: holding pin made of composite material of graphite and thermosetting resin.

As shown in Table 1, in Example 1 and Example 2 constituting the holding pin 20x of the first type holding pin 20A, the wafer could be held satisfactorily without spinning during the ion-implantation. In addition, the formed SOI layer of each SOI substrate had a small thickness range. In Comparative Example 1 where each wafer was held by three first type holding pins 20A, although the thickness range of the SOI layer was similar to those of Example 1 and Example 2, each wafer spun during the ion-implantation. In Comparative Example 2 where the wafer was held by three second type holding pins 20B, although the wafer did not spin during the ion implantation, thickness range of the SOI layer was larger than those of Example 1 and Example 2.

### Experiment B

In Experiment B, three holding pins were selected from one second type holding pin 20B and two first type holding pins 20A, and three case each positioning the second type holding pin 20B in the different position were examined.

In Example 3, the holding pin 20z was constituted of the second type holding pin 20B. In Example 4, the holding pin 20y was constituted of the second type holding pin 20B. In Comparative Example 3, the holding pin 20x positioned at the tail end with respect to the swinging direction of the wafer was constituted of the second type holding pin 20B.

In each of Examples 3, 4, and Comparative Example 3, ion-implantation conditions were controlled such that implantation energy of 216 keV and implantation dose of 2.5×10¹⁷ atoms/cm² were applied for the first time oxygen ion implantation, and implantation energy of 200 keV and implantation dose of 4.0×10¹⁵ atoms/cm² were applied for the second time oxygen ion implantation. The results of evaluation were shown in Table 2.

TABLE 2

| | | | | | Thickness |
|---|---|---|---|---|---|
| | | | | | range of SOI |
| | | | | Spinning of | layer |
| | 20x | 20y | 20z | wafer | (Å) |
| Example 3 | 20A | 20A | 20B | absent | 43 |
| | (resin) | | (graphite | absent | 40 |
| | | | containing | absent | 41 |
| | | | composite) | absent | 46 |
| Example 4 | 20A | 20B | 20A | absent | 38 |
| | | | | absent | 40 |
| | | | | absent | 41 |
| | | | | absent | 41 |
| Comparative | 20B | 20A | 20A | absent | 57 |
| Example 3 | | | | absent | 59 |
| | | | | absent | 54 |
| | | | | absent | 59 |

20A: holding pin made of thermosetting resin
20B: holding pin made of composite material of graphite and thermosetting resin.

As shown in Table 2, compared to Examples 3 an 4 where the holding pin 20x was constituted of the second type holding pin 20A, Comparative Example 4 where the holding pin 20x was constituted of the second type holding pin 20B showed a large thickness range of the SOI layer. In any of the case, spinning of the wafer was not observed

From the results described above, it was confirmed that the inclined thermal distribution could be suppressed by positioning of the first type holding pin made of thermosetting resin, and that spinning of the wafer could be suppressed by the second type holding pins made of material containing graphite. That is, the constitution of the present invention is effective for solving the problems.

While preferred embodiments of the invention have been described and illustrated above, it should be understood that the above-explained forms and combinations of materials are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An ion-implanting apparatus comprising a holding unit that holds at least a semiconductor wafer and swings the wafer along a circular orbit,
wherein an ion-beam is irradiated to a region that overlaps a part of the circular orbit to implant ions in the wafer;
the holding unit comprises three or more holding pins that hold the wafer by being in contact with a circumference edge of the wafer;
the holding pins include a first type holding pin at least a portion of which being in contact with an edge of the wafer is made of a material selected from a thermo-setting resin and a photo-setting resin, and a second type holding pin at least a portion of which being in contact with the wafer is made of a material that contains graphite; and
the first type holding pin of the plurality of holding pins is placed at a tail end position with respect to a direction of swinging the wafer.

2. The ion-implanting apparatus according to claim 1, wherein the first type holding pin is made of material that comprises polyimide resin having a resistivity of 0.1 Ω·cm or more and 1.00 Ω·cm or less.
